(19) United States
(12) Patent Application Publication
(10) Pub. No.: US 2007/0210846 A1
(43) Pub. Date: Sep. 13, 2007

(54) Inverter gate delay line with delay adjustment circuit

(75) Inventor: Hui-Min Wang, Hsinhua (TW)

Correspondence Address: John Chen;Room 303, 3F., No 25, Sec. 1, Changan E. Road, Taipei, 10441, TW

(73) Assignee: Himax Technologies, Inc.

(21) Appl. No.: 11/371,927

(22) Filed: Mar. 10, 2006

(51) Int. Cl. H03H 11/26

(52) U.S. Cl. 327/276

(57) ABSTRACT

The present invention provides a digital circuit comprising an inverter gate delay line and a delay adjustment circuit. The inverter gate delay line comprises a series of a plurality of inverter gates that receives a serial data. The delay adjustment circuit comprises a replica inverter gate delay line comprising a series of a plurality of inverter gates and being configured to receive a first signal, a plurality of flip flops, each one of the plurality of flip flops electrically connected to the corresponding inverter gates of the replica inverter gate delay line, wherein the plurality of flip flops store binary information and the first flip flop of the plurality of flip flops receives a second signal which has a time delay with respect to the first signal, an encoder being electrically connected to the plurality of flip flops and determining the numbers of the needed inverter gates of the inverter gate delay line based on the binary information stored in the plurality of flip flops, and a delay selector being electrically connected to the encoder and the plurality of inverter gates of the inverter gate delay line and causing the serial data delayed by the inverter gates of the inverter gate delay line, wherein the numbers of the inverter gates of the inverter gate delay line are determined by an output of the encoder.

### BACKGROUND OF THE PRESENT INVENTION

1. Field of Invention

The present invention relates to electrical circuitry and in particular to an apparatus and method for determining the time delay in signals received at an inverter gate delay line.

2. Description of Related Arts

Delay elements are constructed from various logic functions such as inverters, for insertion of predetermined delay in signal path. If a multitude of these delay cells are required for parallel data transmission, these cells are subjected to effects of temperature, power supply voltage, manufacturing process and on-chip mismatches among these individual cells. Delay elements such as an inverter gate delay line are widely utilized in various data transmission systems. The main application is the insertion of known time interval into a signal path to either increase delay or to modify the signal shape, such as duty cycle and period. All delay elements take advantage of intrinsic propagation delay through the transistors. Adjustments of transistor size (width, length) and operating conditions (capacitive load, temperature, voltage supply, etc.) will result in some degree control of signal delay. The manufacturing process causes chip-to-chip variations in delay elements.

In the conventional technique, an inverter gate delay line is usually utilized for insertion of predetermined delay in signal path. However, the inverter gate delay line is also subjected to effects of temperature, power supply voltage, manufacturing process and on-chip mismatches among these individual gates. In other words, the delay time of the inverter gate delay line is varied with effects of temperature, power supply voltage, manufacturing process and on-chip mismatches among these individual gates.

One additional and significant cause of delay variations are thermal gradients across the chip with non-uniformly distributed power dissipation of certain functions such as clock and bus drivers. As the power dissipation varies in time by changing the driving sources, the thermal gradient will change the intended signal delays among the data channels.

Accordingly, it would be advantageous to have an improved delay mechanism for data channels that can determine the time delay in signals received at the inverter gate delay line, which is insensitive to effects of temperature, power supply voltage, and manufacturing process among these individual gates.

### SUMMARY OF THE PRESENT INVENTION

A main object of the present invention is to provide an inverter gate delay line with a delay adjustment circuit that can determine the time delay in signals received at the inverter gate delay line, which is insensitive to effects of temperature, power supply voltage, or manufacturing process among these individual inverter gates.

Another object of the present invention is to provide an inverter gate delay line with a delay adjustment circuit for optimizing the insertion of predetermined delay in a signal path. That is, the present invention provides an improved delay mechanism for data channels that can determine the time delay in signals received at the inverter gate delay line, which is insensitive to effects of temperature, power supply voltage, or manufacturing process among these individual gates.

Accordingly, in order to accomplish the above objects, the present invention provides a digital circuit, comprising:
an inverter gate delay line comprising a series of a plurality of inverter gates that receives a serial data; and
a delay adjustment circuit comprising:
   a replica inverter gate delay line comprising a series of a plurality of inverter gates and being configured to receive a first signal;
   a plurality of flip flops, each one of the plurality of flip flops electrically connected to the corresponding inverter gates of the replica inverter gate delay line, wherein the plurality of flip flops store binary information and the first flip flop of the plurality of flip flops receives a second signal which has a time delay with respect to the first signal;
   an encoder being electrically connected to the plurality of flip flops and determining the numbers of the needed inverter gates of the inverter gate delay line based on the binary information stored in the plurality of flip flops; and
   a delay selector being electrically connected to the encoder and the plurality of inverter gates of the inverter gate delay line and causing the serial data delayed by the inverter gates of the inverter gate delay line, wherein the numbers of the inverter gates of the inverter gate delay line are determined by an output of the encoder.

These and other objectives, features, and advantages of the present invention will become apparent from the following detailed description, the accompanying drawings, and the appended claims.

### BRIEF DESCRIPTION OF THE DRAWINGS

FIG. 1 is a circuit diagram of an inverter gate delay line with a delay adjustment circuit according to a preferred embodiment of the present invention.

FIG. 2 is the waveform of the signal PA and the signal PB with a rising edge according to the above-preferred embodiment of the present invention.

### DETAILED DESCRIPTION OF THE PREFERRED EMBODIMENT

In the following detailed description of the present invention, numerous specific details are set forth in order to provide a thorough understanding of the present invention. However, it will be obvious to one skilled in the art that the present invention may be practiced without these specific details. In other instances well known methods, procedures, components, and circuits have not been described in detail so as not to unnecessarily obscure aspects of the present invention.

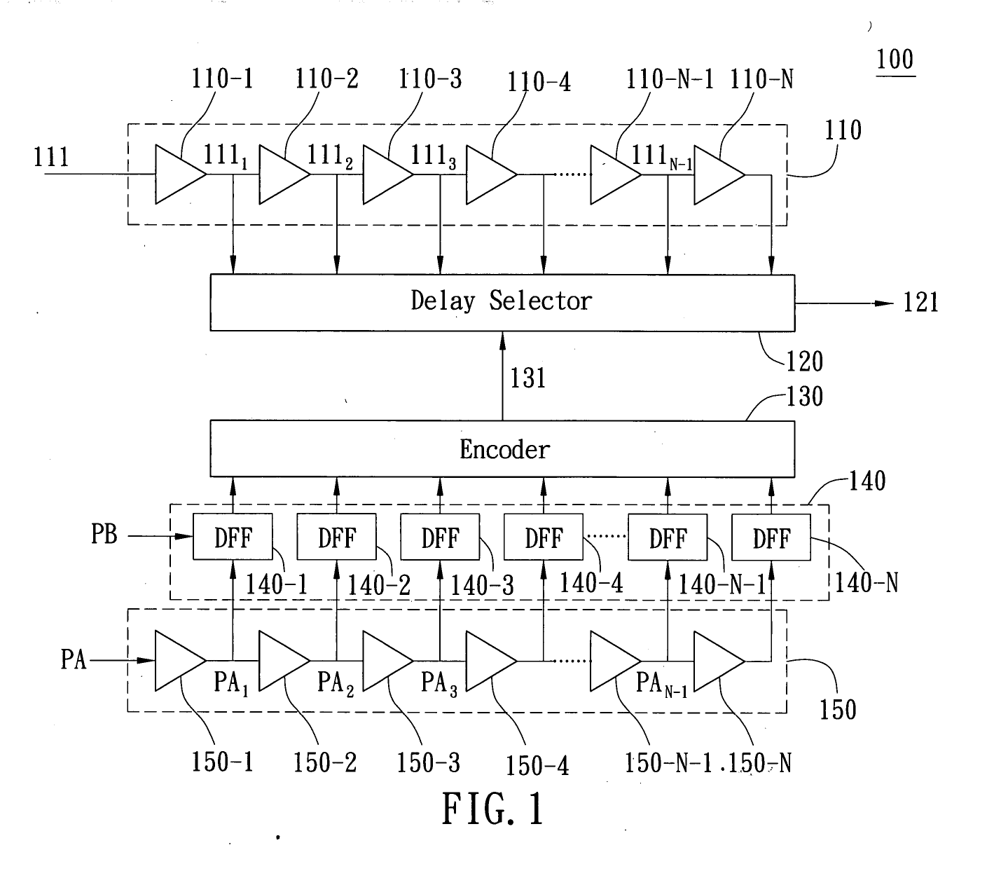

Referring to FIG. 1 of the drawings, a digital circuit 100 comprises an inverter gate delay line 110 and a delay adjustment circuit. The delay adjustment circuit comprises a delay selector 120, an encoder 130, an array 140 of D-type flip flops (DFFs) 140-1 through 140-N, a replica inverter gate delay line 150. The replica inverter gate delay line 150 has the same circuit configuration with the inverter gate delay line 110 such as transistor size (width, length) and operating conditions (capacitive load, temperature, voltage supply, etc.). The delay adjustment circuit is utilized to determine the time delay in serial data received at the inverter gate delay line 110, which is insensitive to effects of temperature, power supply voltage, or manufacturing process among these individual gates.

In this embodiment, the inverter gate delay line 110 comprises a series of inverter gates 110-1 through 190-N, where N is a natural number predetermined by the designers or manufacturers of the present invention and will vary depending on the implementation. The inverter gate 110-1 of the inverter gate delay line 110 receives a serial data 111. Each inverter gates 110-1 through 110-N-1 transfers its contents to the next inverter gate. That is, on each assertion of a reference clock signal (not shown in the figures), the serial data 111 is transmitted to the inverter gate 110-1, the delayed serial data 111₁ is transmitted from the inverter gate 110-1 to the inverter gate 110-2, the delayed serial data 111₂ is transmitted from the inverter gate 110-2 to the inverter gate 110-3, the delayed serial data 111₃ is transmitted from the inverter gate 110-3 to the inverter gate 110-4, . . . , the delayed serial data 111_{N-2} is transmitted from the inverter gate 110-N-2 to the inverter gate 110-N-1, and the delayed serial data 111_{N-1} is transmitted from the inverter gate 110-N-1 to the inverter gate 110-N. In other words, the serial data 111 is gradually transmitted to the next inverter gate in response to the reference clock signal. Each output of the inverter gates 110-1 through 110-N is electrically connected with the delay selector 120 and could transfer its contents to the delay selector 120 in response to the reference clock signal. The output of the delay selector 120 is determined by the output value of the encoder 130. That is, in response to the output value of the encoder 130, the delay selector 120 is loaded one of the outputs of the inverter gates 110-1 through 110-N. The serial data 111 is delayed by the multitude of inverter gates which are determined by the output value of the encoder 130.

The replica inverter gate delay line 150 comprises a series of inverter gates 150-1 through 150-N, wherein N where N is a natural number predetermined by the designers or manufacturers of the present invention and will vary depending on the implementation. The replica inverter gate delay line 150 has the same circuit configuration with the inverter gate delay line 110 such as transistor size (width, length) and operating conditions (capacitive load, temperature, voltage supply, etc.). The replica inverter gate delay line 150 receives a rising (or falling) edge of a signal PA. Each inverter gates 150-1 through 150-N-1 transfers its contents to the next inverter gate. That is, on each assertion of the reference clock signal (not shown in the figures), the signal PA is transmitted to the inverter gate 150-1, the delayed signal PA₁ is transmitted from the inverter gate 150-1 to the inverter gate 150-2, the delayed signal PA₂ is transmitted from the inverter gate 150-2 to the inverter gate 150-3, the delayed signal PA₃ is transmitted from the inverter gate 150-3 to the inverter gate 150-4, . . . , the delayed signal PA_{N-2} is transmitted from the inverter gate 150-N-2 to the inverter gate 150-N-1, and the delayed signal PA_{N-1} is transmitted from the inverter gate 150-N-1 to the inverter gate 150-N. In other words, the signal PA is gradually transmitted to the next inverter gate in response to the reference clock signal. Each output of the inverter gates 150-1 through 150-N is connected to the corresponding D-type flip flops (DFFs) 140-1 through 140-N respectively. In other words, the output values of the inverter gates 150-1 through 150-N are respectively stored in the corresponding D-type flip flops (DFFs) 140-1 through 140-N in response to the reference clock signal.

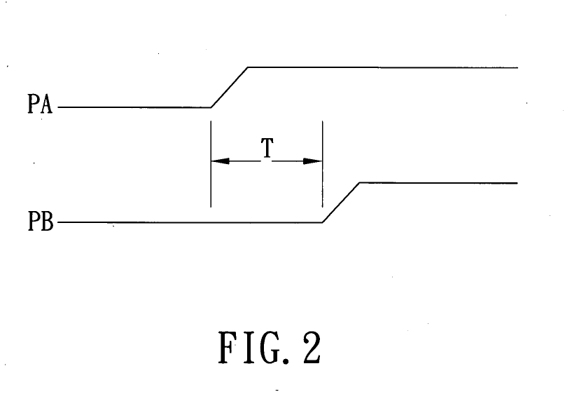

A signal PB is transmitted to the D-type flip flop (DFF) 140-1 after the inverter gate 150-1 receives the signal PA for a period of time T, wherein the signal PB has a time delay T with respect to the signal PA as shown in FIG. 2. The time delay T is proportional to the period of the reference clock signal. For example, the signal PB is transmitted to the D-type flip flop (DFF) 140-1 after the inverter gate 150-1 receives the signal PA for a period of time T. The D-type flip flop (DFF) 140-1 is to store one bit of binary information at logic level 1 because the basic function of the D-type flip flop (DFF) is to store one bit of binary information at logic level 1 or 0. Assume that the rising-edge signal PA is transmitted from the inverter gate 150-1 to the inverter gate 150-4 during the period of time T. Hence the D-type flip flop (DFF) 140-4 is to store one bit of binary information at logic level 1. The other D-type flip flops (DFFs) are to store one bit of binary information at logic level 0 except that the D-type flip flops (DFFs) 140-1 and 140-4 are to store one bit of binary information at logic level 1 in response to the reference clock signal. Hence the binary information stored in the D-type flip flops could be defined as “1001000000 . . . 00”. Furthermore, the outputs of the D-type flip flops (DFFs) 140-1 through 140-N are electrically connected to the encoder 130. The encoder 130 could calculate the numbers of the needed inverter gates of the inverter gate delay line 110 based on the binary information stored in the D-type flip flops. In the above example, the numbers of the needed inverter gates of the inverter gate delay line 110 are three. Accordingly, the encoder 130 outputs a signal 131 to the delay selector 120 to select the numbers of the needed inverter gates of the inverter gate delay line 110 for insertion of predetermined delay in signal path. That is, there exist three needed inverter gates of the inverter gate delay line 110 for insertion of predetermined delay in signal path in response to the signal 131. The delay selector 120 will receive the output of the inverter gate 110-3 and output the optimized delay serial data 121. In conclusion, the present invention provides an inverter gate delay line with a delay adjustment circuit for optimizing the insertion of predetermined delay in signal path. That is, the present invention provides an improved delay mechanism for data channels that can determine the time delay in signals received at the inverter gate delay line, which is insensitive to effects of temperature, power supply voltage, or manufacturing process among these individual gates.

From the forgoing descriptions, it can be shown that the above objects have been substantially achieved. The present invention effectively provides an inverter gate delay line with a delay adjustment circuit for determining and optimizing the time delay in signals received at an inverter gate delay line which is insensitive to effects of temperature, power supply voltage, or manufacturing process among these individual cells.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A digital circuit, comprising:
an inverter gate delay line comprising a series of a plurality of inverter gates that receives a serial data; and
a delay adjustment circuit comprising:
a replica inverter gate delay line comprising a series of a plurality of inverter gates and being configured to receive a first signal;
a plurality of flip flops, each one of the plurality of flip flops electrically connected to said corresponding inverter gates of said replica inverter gate delay line, wherein said plurality of flip flops store binary information and the first flip flop of said plurality of flip flops receives a second signal which has a time delay with respect to said first signal;
an encoder being electrically connected to said plurality of flip flops and determining the numbers of the needed inverter gates of said inverter gate delay line based on said binary information stored in said plurality of flip flops; and
a delay selector being electrically connected to said encoder and said plurality of inverter gates of said inverter gate delay line and causing said serial data delayed by said inverter gates of said inverter gate delay line, wherein the numbers of said inverter gates of said inverter gate delay line are determined by an output of said encoder.

2. The digital circuit, as recited in claim 1, wherein said plurality of flip flops are D-type flip flops.

3. The digital circuit, as recited in claim 1, wherein said plurality of inverter gates of said replica inverter gate delay line are identical to said plurality of inverter gates of said inverter gate delay line.

4. The digital circuit, as recited in claim 2, wherein said plurality of inverter gates of said replica inverter gate delay line are identical to said plurality of inverter gates of said inverter gate delay line.

5. The digital circuit, as recited in claim 1, wherein said time delay in said serial data received at said inverter gate delay line which is insensitive to effects of temperature, power supply voltage, or manufacturing process among these individual inverter gates.

6. The digital circuit, as recited in claim 4, wherein said time delay in said serial data received at said inverter gate delay line which is insensitive to effects of temperature, power supply voltage, or manufacturing process among these individual inverter gates.

7. The digital circuit, as recited in claim 1, wherein said first signal is one of a rising-edge signal and a falling-edge signal.

8. The digital circuit, as recited in claim 1, wherein said second signal is one of a rising-edge signal and a falling-edge signal.

9. A method for providing a time delay in a digital circuit, comprising the steps of:
providing an inverter gate delay line which comprises a series of a plurality of inverter gates for receiving a serial data;
providing a replica inverter gate delay line which comprises a series of a plurality of inverter gates and is configured to receive a first signal;
providing a plurality of flip flops, wherein the first flip flop of said plurality of flip flops receives a second signal which has a time delay with respect to said first signal and said plurality of flip flops store binary information generated by said first signal and said second signal;
determining the numbers of the needed inverter gates of said inverter gate delay line based on said binary information stored in said plurality of flip flops; and
causing said serial data delayed by said inverter gates of said inverter gate delay line, wherein the numbers of said inverter gates of said inverter gate delay line are determined by an output of said encoder.

10. The method, as recited in claim 9, wherein said plurality of flip flops are D-type flip flops.

11. The method, as recited in claim 9, wherein said plurality of inverter gates of said replica inverter gate delay line are identical to said plurality of inverter gates of said inverter gate delay line.

12. The method, as recited in claim 11, wherein said plurality of inverter gates of said replica inverter gate delay line are identical to said plurality of inverter gates of said inverter gate delay line.

13. The method, as recited in claim 9, wherein said time delay in said serial data received at said inverter gate delay line which is insensitive to effects of temperature, power supply voltage, or manufacturing process among these individual inverter gates.

14. The method, as recited in claim 12, wherein said time delay in said serial data received at said inverter gate delay line which is insensitive to effects of temperature, power supply voltage, or manufacturing process among these individual inverter gates.

15. The method, as recited in claim 9, wherein said first signal is one of a rising-edge signal and a falling-edge signal.

16. The method, as recited in claim 9, wherein said second signal is one of a rising-edge signal and a falling-edge signal.
